(19) United States
(12) Patent Application Publication
(10) Pub. No.: US 2024/0186213 A1
(43) Pub. Date: Jun. 6, 2024

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Jae Jin REE, Gyeonggi-do (KR); Sang Hyeon LEE, Incheon (KR); Yi Seul HAN, Incheon (KR); Geon Du GIM, Gwangju (KR); Hun Jung LIM, Sejong (KR)

(73) Assignee: Amkor Technology Singapore Holding Pte. Ltd., Valley Point #12-03 (SG)

(21) Appl. No.: 18/076,245

(22) Filed: Dec. 6, 2022

(51) Int. Cl. H01L 23/367; H01L 21/48; H01L 21/56; H01L 23/00; H01L 23/31; H01L 23/373; H01L 25/16

(52) U.S. Cl. CPC H01L 23/3675; H01L 21/4882; H01L 21/563; H01L 23/3135; H01L 23/3735; H01L 24/16; H01L 24/32; H01L 24/73; H01L 25/165; H01L 2224/16227; H01L 2224/32225; H01L 2224/73204; H01L 2924/1611; H01L 2924/1616; H01L 2924/1619; H01L 2924/16235; H01L 2924/16251; H01L 2924/16315

(57) ABSTRACT

In one example, an electronic device includes a substrate and a cover structure. The cover structure includes an upper cover wall comprising an upper wall outer surface and an upper wall inner surface opposite to the upper wall outer surface, cover sidewalls extending from the upper wall inner surface and coupled to the substrate. The upper cover wall and the cover sidewalls define a cavity. A channel structure is in the upper cover wall extending inward from the upper wall inner surface. A first electronic component is coupled to the substrate within the cavity and a thermal interface material (TIM) is coupled to the upper wall inner surface and the first electronic component. A portion of the TIM is within the channel structure. Other examples and related methods are also disclosed herein.

### CROSS-REFERENCE TO RELATED APPLICATION

Not Applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, and 2E show cross-sectional views of an example method for manufacturing an example electronic device.

FIG. 2D-1 shows a bottom-up view of an example cover structure for an electronic device.

FIGS. 3A, 3B, 3C, 3D, and 3E show cross-sectional views of an example method for manufacturing an example cover structure.

FIG. 4 shows cross-sectional views of an example electronic device.

FIGS. 5A, 5B, and 5C show cross-sectional views of an example method for manufacturing an example electronic device.

FIG. 5B-1 shows a bottom-up view of an example cover structure for an electronic device.

FIGS. 6A, 6B, 6C, and 6D show cross-sectional views of an example method for manufacturing an example cover structure.

FIGS. 7A, 7B, 7C, 7D, and 7E show cross-sectional views of an example method for manufacturing an example cover structure.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. Crosshatching lines may be used throughout the figures to denote different parts but not necessarily to denote the same or different materials. Throughout the present disclosure, like reference numbers denote like elements. Accordingly, elements with like element numbering may be shown in the figures but may not be necessarily repeated herein for the sake of brevity.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly connected by one or more other elements. For example, if element A is coupled to element B, then element A can be directly contacting element B or indirectly connected to element B by an intervening element C. As used herein, the term “coupled” can refer to an electrical coupling or a mechanical coupling. Similarly, the terms “over” or “on” may be used to describe two elements directly contacting each other or to describe two elements indirectly connected by one or more other elements.

### DESCRIPTION

In an example, an electronic device includes a substrate and a cover structure. The cover structure includes an upper cover wall comprising an upper wall outer surface and an upper wall inner surface opposite to the upper wall outer surface, cover sidewalls extending from the upper wall inner surface and coupled to the substrate. The upper cover wall and the cover sidewalls define a cavity. A channel structure is in the upper cover wall extending inward from the upper wall inner surface. A first electronic component is coupled to the substrate within the cavity and a thermal interface material (TIM) is coupled to the upper wall inner surface and the first electronic component. A portion of the TIM is within the channel structure.

In an example, an electronic device includes a substrate including a conductive structure and a dielectric structure. A lid structure includes an upper lid wall, a lid sidewall, and a channel structure. The upper lid wall includes an upper wall outer surface and an upper wall inner surface opposite to the upper wall outer surface. The lid sidewall extends from the upper lid wall and is coupled to the substrate. The channel structure extends inward from the upper wall inner surface towards the upper wall outer surface. The upper lid wall and the lid sidewall define a lid cavity. A first electronic component includes a first side, a second side opposite to the first side, and a lateral side connecting the first side to the second side. The lateral side of the first electronic component defines a first footprint and the first side of the first electronic component is coupled to the conductive structure within the lid cavity. A TIM is interposed between the second side of the first electronic component and the upper lid wall. At least a portion of the channel structure is laterally outside of the first footprint, and at least a portion of the TIM is inside the channel structure.

In an example, a method of manufacturing an electronic device includes providing a substrate including a conductive structure and a dielectric structure, providing a first electronic component including a first side and a second side opposite to the first side, and providing a lid structure. The lid structure includes an upper lid wall comprising an upper wall outer surface and an upper wall inner surface opposite to the upper wall outer surface, lid sidewalls extending from the upper lid wall, and a channel structure extending inward from the upper wall inner surface towards the upper wall outer surface. The method includes providing a TIM, coupling the first side of the first electronic component to the conductive structure, and coupling the upper lid wall to the second side of the first electronic component with the TIM and coupling the lid sidewalls to the substrate. The channel structure accommodates flow of the TIM in response to the coupling of the upper lid wall to the second side of the first electronic component.

Other examples are included in the present disclosure. Such examples may be found in the figures, in the claims, or in the description of the present disclosure.

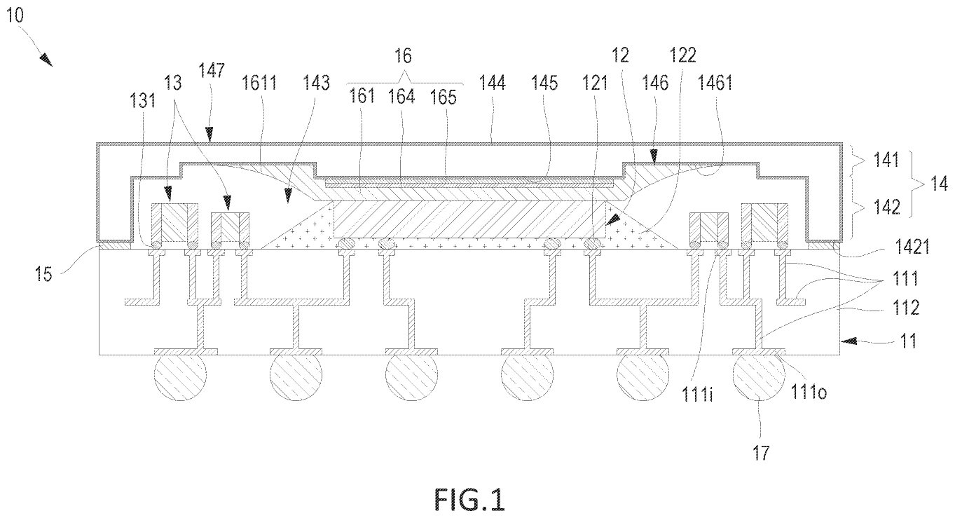

FIG. 1 shows a cross-sectional view of an example electronic device 10. In the example shown in FIG. 1, electronic device 10 can comprise substrate 11, electronic component 12, electronic components 13, cover structure 14, lid bonding material 15, thermal interface material (TIM) 16, and external interconnects 17.

Substrate 11 can comprise conductive structure 111 and dielectric structure 112. Electronic component 12 can comprise component terminals 121 and underfill 122. Electronic components 13 can comprise component terminals 131. Cover structure 14 can comprise upper lid wall 141, lid sidewalls 142, lid cavity 143, TIM channels 146, and coating 147. Lid upper wall 141 can include upper wall outer surface 144 and upper wall inner surface 145. TIM 16 can comprise TIM layer 161, surface treatment layer 164, and metal TIM 165. In some examples, a portion 1611 of TIM 16 can be located in TIM channels 146.

Substrate 11, cover structure 14, lid bonding material 15, TIM 16, and external interconnects 17 can comprise or be referred to as an electronic package or a package. The electronic package can protect electronic components 12 and 13 from exposure to external elements and/or environments. The electronic package can also provide electrical coupling between electronic component 12 and electronic components 13 and between electronic components 12 and 13 and an external component or other electronic packages.

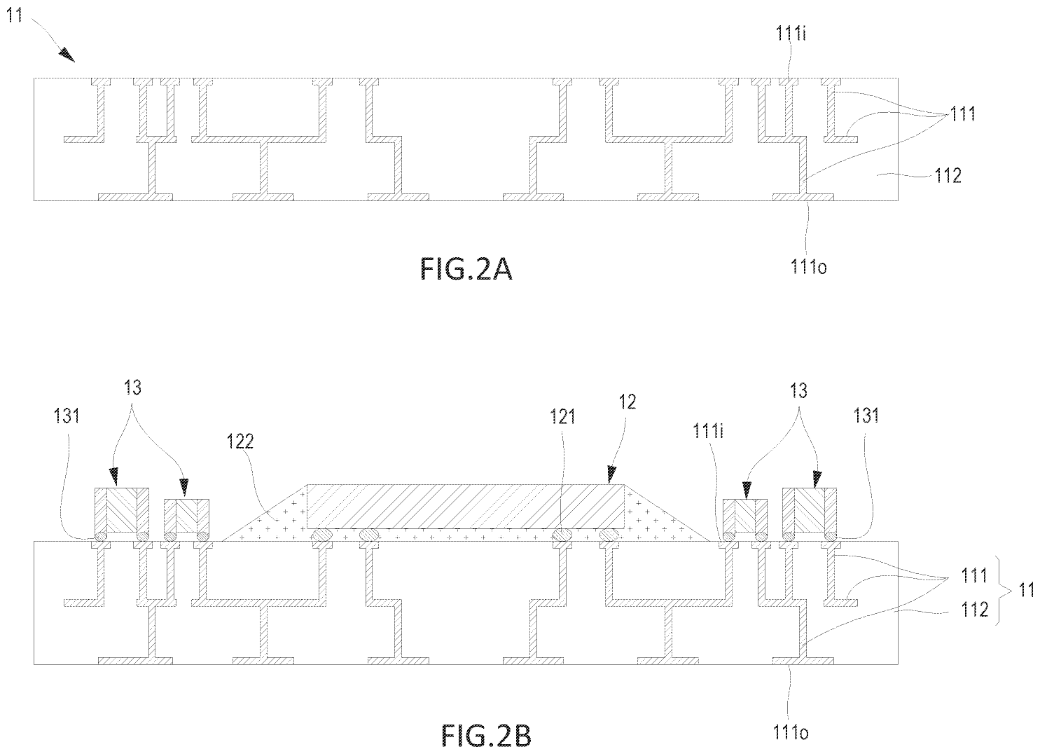

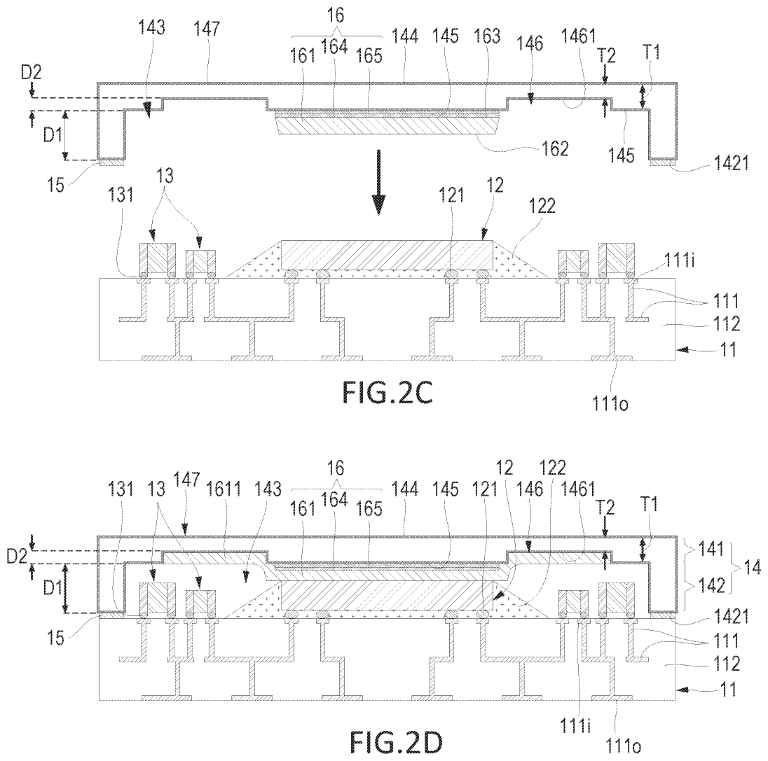

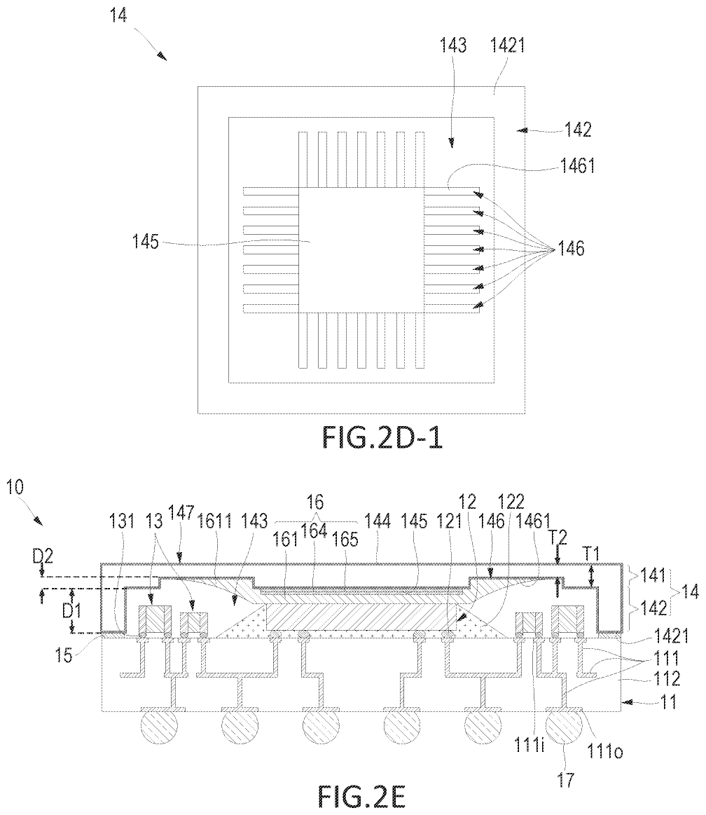

FIGS. 2A to 2E show cross-sectional views of an example method for manufacturing an example electronic device, such as electronic device 10 in FIG. 1. FIG. 2D-1 shows a bottom-up view of an example cover structure, such as cover structure 14 in FIG. 1.

FIG. 2A is a cross-sectional view of electronic device 10 at an early stage of manufacture. In the example shown in FIG. 2A, substrate 11 can be provided. In some examples, substrate 11 can comprise or be referred to as a laminate substrate, a redistribution layer (RDL) substrate, or a ceramic substrate. Substrate 11 comprises conductive structure 111 and dielectric structure 112. In some examples, the thickness of substrate 11 can range from about 300 micrometers (μm) to about 2000 μm.

In some examples, conductive structure 111 can comprise or be referred to as one or more conductors, conductive materials, conductive paths, conductive layers, redistribution layers (RDLs), wiring layers, traces, vias, pads, or under bump metallization (UBM). In some examples, one or more of the conductive layers can be interleaved with dielectric layers of dielectric structure 112. In some examples, conductive structure 111 can comprise copper, aluminum, palladium, titanium, tungsten, titanium/tungsten, nickel, gold, or silver. In some examples, conductive structure 111 can be provided by sputtering, electroless plating, electrolytic plating, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, a portion of conductive structure 111 can be exposed to the top side and the bottom side of substrate 11. For example, conductive structure 111 can include inner contact pads or lands 111i and outer contact pads or lands 1110. Inner contact pads 111i can be exposed on the top side of substrate 11 and outer contact pads 1110 can be exposed on the bottom side of substrate 11. Conductive structure 111 can be coupled to electronic components 12 and 13 (FIG. 1) and external interconnects 17 (FIG. 1). For example, electronic components 12 and 13 can be coupled to inner contact pads 111i and external interconnects 17 can be coupled to outer contact pads 1110. Conductive structure 111 can transmit signals, currents, or voltages within substrate 11. In some examples, the thickness of conductive structure 111 can range from about 3 μm to about 50 μm. The thickness of conductive structure 111 can refer to individual layers of conductive structure 111.

In some examples, dielectric structure 112 can comprise or be referred to as one or more dielectrics, dielectric materials, dielectric layers, passivation layers, insulating layers, or protective layers. In some examples, dielectric structure 112 can have a structure where one or more dielectric layers are stacked. In some examples, dielectric structure 112 can comprise polymer, polyimide (PI), benzocyclobutene (BCB), polybenzoxazole (PBO), bismaleimide triazine (BT), a molding material, phenolic resin, epoxy, silicone, or acrylate polymer. Dielectric structure 112 can be in contact with conductive structure 111. Dielectric structure 112 can expose portions of conductive structure 111. In some examples, dielectric structure 112 can maintain the external shape of substrate 11 and can structurally support conductive structure 111. In some examples, dielectric structure 112 can be provided by spin coating, spray coating, printing, oxidation, PVD, CVD, MOCVD, ALD, LPCVD, or PECVD. In some examples, the thicknesses of individual layers of dielectric structure 112 can range from about 3 μm to about 50 μm. The combined thickness of all layers of dielectric structure 112 can define the thickness of substrate 11.

In some examples, substrate 11 can be an RDL substrate. RDL substrates can comprise one or more conductive redistribution layers and one or more dielectric layers that (a) can be formed layer by layer over an electronic device to which the RDL substrate is to be electrically coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Substrates, as disclosed herein, can comprise RDL substrates.

In some examples, substrate 11 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate which omits the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Substrates, as disclosed herein, can comprise pre-formed substrates.

FIG. 2B shows a cross-sectional view of electronic device 10 at a later stage of manufacture. In the example shown in FIG. 2B, electronic components 12 and 13 can be provided on substrate 11. Electronic components 12 and 13 can be coupled to conductive structure 111 of substrate 11. For example, electronic components 12 and 13 can be coupled to inner contact pads 111i.

In some examples, electronic component 12 can comprise or be referred to as one or more dies, chips, or packages. In some examples, electronic component 12 can comprise a memory, a digital signal processor (DSP), a microprocessor, a network processor, a power management processor, an audio processor, an RF circuit, a wireless baseband system-on-chip (SoC) processor, a sensor, or an application specific integrated circuit (ASIC). In some examples, the height of electronic component 12 can range from about 80 μm to about 800 μm.

Electronic component 12 can comprise component terminals 121. Component terminals 121 can comprise or be referred to as bumps, pillars, pads, or solder balls. Component terminals 121 can be provided on the bottom side of electronic component 12. Component terminals 121 can be provided as electrical contacts between electronic component 12 and substrate 11. Component terminals 121 can be coupled to conductive structure 111. For example, component terminals 121 can be coupled to inner contact pads 111i of conductive structure 111 by a mass reflow process, a thermal compression process, or a laser bonding process. In some examples, component terminals 121 can comprise copper (Cu), lead (Pb), tin (Sn), aluminum (Al), palladium (Pd), titanium (Ti), tungsten (W), titanium/tungsten (Ti/W), nickel (Ni), gold (Au), or silver (Ag). In some examples, the thickness (or height) of each component terminal 121 can range from about 30 μm to about 1000 μm.

In some examples, underfill 122 can be provided between electronic component 12 and substrate 11. In some examples, underfill 122 can comprise or be referred to as capillary underfill (CUF), molded underfill (MUF), non-conductive paste (NCP), non-conductive film (NCF), or anisotropic conductive film (ACF). In some examples, underfill 122 can comprise epoxy, a thermoplastic material, a thermosetting material, polyimide, polyurethane, a polymeric material, filled epoxy, a filled thermoplastic material, a filled thermosetting material, filled polyimide, filled polyurethane, a filled polymeric material, or a fluxing underfill. Underfill 122 can cover or surround component terminals 121. Underfill 122 contacts the top side of substrate 11 and the bottom side of electronic component 12. In some examples, underfill 122 can cover, at least, a portion of lateral sides of electronic component 12. In some examples, underfill 122 can prevent or reduce occurrences of electronic component 12 being separated from substrate 11. In some examples, the thickness of underfill 122 can range from about 80 μm to about 800 μm.

In some examples, electronic components 13 can each comprise or be referred to as a passive device or a passive component. For example, electronic component 13 can comprise a capacitor, an inductor, or a resistor. In some examples, the height of electronic component 13 can range from about 50 μm to about 2000 μm.

Electronic components 13 can comprise component terminals 131. In some examples, component terminals 131 can be provided on the bottom side or opposite sides of electronic component 13. Component terminals 131 can be provided as electrical contacts between electronic component 13 and substrate 11. Component terminals 131 can be coupled to conductive structure 111. For example, component terminals 131 can be coupled to inner contact pads 111i of conductive structure 111 by a mass reflow process, a thermal compression process, or a laser bonding process. In some examples, component terminals 131 can comprise copper (Cu), lead (Pb), tin (Sn), aluminum (Al), palladium (Pd), titanium (Ti), tungsten (W), titanium/tungsten (Ti/W), nickel (Ni), gold (Au), or silver (Ag). In some examples, the thickness of each of component terminals 131 can range from about 5 μm to about 200 μm.

FIGS. 2C and 2D show cross-sectional views of electronic device 10 at a later stage of manufacture. FIG. 2D-1 shows a bottom-up view of cover structure 14. In the example shown in FIGS. 2C and 2D, cover structure 14 can be provided over substrate 11 and electronic components 12 and 13. Cover structure 14 can be coupled proximate the edge of substrate 11. Cover structure 14 can cover the top sides of electronic components 12 and 13. In some examples, cover structure 14 can comprise or be referred to as a lid, a lid structure, or a shield. In some examples, cover structure 14 can comprise a metal material, such as copper, a copper alloy, nickel, a nickel alloy, or stainless steel. Cover structure 14 can comprise upper lid wall 141 and lid sidewalls 142. Upper lid wall 141 and lid sidewalls 142 can define lid cavity 143. In some examples, the thickness of cover structure 14 can range from about 300 μm to about 4000 μm. The thickness of cover structure 14 can be defined as the sum of the thickness of upper lid wall 141 and the thickness of lid sidewall 142. Upper lid wall 141 also can be referred to as an upper cover wall. Lid sidewalls 142 also can be referred to as cover sidewalls. Lid cavity 143 also can be referred to as a cavity.

Lid cavity 143 can be defined by upper lid wall 141 and lid sidewalls 142. Electronic components 12 and 13 can be accommodated in lid cavity 143. In some examples, the depth D1 of lid cavity 143 can range from about 50 μm to about 1600 μm. The depth D1 of lid cavity 143 can refer to a distance between upper lid inner surface 145 and sidewall bottom 1421. The depth D1 of lid cavity 143 can correspond to the thickness of lid sidewalls 142.

In some examples, coating 147 can be provided on the surface of cover structure 14. For example, coating 147 can be provided on surfaces of upper lid wall 141 and lid sidewalls 142. In some examples, coating 147 can comprise or be referred to as a conductive coating or a plating. In some examples, coating 147 can comprise an electrically conductive material, such as nickel, gold, silver, platinum, or tin. In some examples, coating 147 can be provided by electroless plating, electrolytic plating, or sputtering. In some examples, the thickness of coating 147 can range from about 3 μm to about 15 μm.

Upper lid wall 141 can include upper lid outer surface 144 and upper lid inner surface 145. Upper lid inner surface 145 opposite (i.e., oriented away from) upper lid inner surface 144. In some examples, upper lid wall 141 can be coupled to the top side of electronic component 12 through TIM 16. In some examples, TIM 16 can be provided on upper lid inner surface 145 of upper lid wall 141 and upper lid wall 141 can be seated or pressed on electronic component 12. In some examples, upper lid wall 141 can be coupled to the top side of electronic component 12 by curing TIM 16. Lid sidewalls 142 can be provided proximate the edge or around the perimeter of upper lid inner surface 145. A central portion of upper lid inner surface 145 can be located over electronic component 12. In some examples, the area (or footprint) of the central portion of upper lid inner surface 145 can be equal to or greater than the area (or footprint) of electronic component 12. In some examples, the thickness T1 of upper lid wall 141 can range from about 200 μm to about 3000 μm. The thickness T1 of upper lid wall 141 can refer to a distance between upper lid outer surface 144 and upper lid inner surface 145.

With additional reference to FIG. 2D-1, in some examples, TIM channels 146 can be provided in upper lid inner surface 145 of upper lid wall 141. In some examples, TIM channels 146 can comprise or be referred to as trenches, grooves, or cavities. In some examples, TIM channels 146 can extend from upper lid inner surface 145 toward upper lid outer surface 144. In some examples, TIM channels 146 do not extend all the way through upper lid wall 141 so that a portion of upper lid wall extends over TIM channels 146. In some examples, TIM channels 146 can be formed by milling or by etching. TIM channels 146 can be provided outside the central portion of upper lid inner surface 145 (e.g., outside a footprint of electronic component 12). TIM channels 146 can be provided between the central portion upper lid inner surface 145 lid sidewalls 142. As shown in FIG. 2D-1, in some examples, TIM channels 146 can include a plurality of channels spaced apart from one another and arranged around the central portion of upper lid inner surface 145. In some examples, the pitch between TIM channels 146 can range from about 200 μm to about 2000 μm. TIM channels 146 are examples of a channel structure. FIG. 2D-1 illustrates an example where portion of upper lid wall 145 comprises a plurality of sides and the plurality of channels 145 is distributed around each of the plurality of sides. It is understood that the shapes or the dimensions of individual TIM channels 146 can be the same or different. It is further understood that additional TIM channels 146 can be included in the corner region of portion 145.

TIM channels 146 can each comprise TIM channel floor 1461. In some examples, the thickness T2 of upper lid wall 141, as measured between upper lid outer surface 144 and TIM channel floor 1461, can range from about 100 μm to about 3900 μm. In some examples, the depth D2 of each TIM channel 146 can range from about 100 μm to about 300 μm. The depth D2 of each of TIM channels 146 can refer to a distance between upper lid inner surface 145 and TIM channel floor 1461.

With particular reference to FIG. 2D, in accordance with various examples, TIM channels 146 can accommodate TIM 16 flowing away from the central portion of upper lid inner surface 145 and the lateral sides of electronic component 12, in response to upper lid wall 141 and TIM 16 being pressed toward electronic component 12. In some examples, TIM 16 flows out (e.g., portion 1611 of TIM 16) and can be drawn into TIM channels 146 by a capillary phenomenon. TIM channels 146 can increase the area of contact between TIM 16 and upper lid wall 141, which tends to improve adhesion strength (or bonding force) between upper lid wall 141 and electronic component 12. Lid channels 146 can also reduce occurrences of TIM 16 flowing onto substrate 11 and/or into contact with conductive structure 11 or electronic components 13, which tends to decrease the chances of TIM 16 causing an electrical short or other fault condition.

In some examples, TIM 16 can comprise or be referred to as an interface material or an adhesive. TIM 16 can be provided between upper lid wall 141 and electronic component 12. In some examples, TIM 16 can contact upper lid inner surface 145 of upper lid wall 141 and the top side of electronic component 12. In some examples, TIM 16 can comprise one layer (e.g., TIM layer 161) or multiple layers (e.g., TIM layer 161 and metal TIM 165). In some examples, the thickness of TIM 16, as measured between upper lid inner surface 145 and the top side of electronic component 12 can range from about 30 μm to about 200 μm.

In some examples, TIM 16 can consist of only TIM layer 161 or can consist of TIM layer 161 and surface treatment layer 164. TIM 16 (or TIM layer 161) can be conductive or non-conductive. TIM 16 (or TIM layer 161) can comprise a metal or a non-metal material. In some examples, the thickness of TIM layer 161 can range from about 30 μm to about 120 μm. In some examples, TIM 16 can be composed of a viscous material, and when upper lid wall 141 is coupled to electronic component 12, portion 1611 of TIM 16 can flow into TIM channels 146. Portion 1611 of TIM 16 (or TIM layer 161) located in TIM channels 146 can be referred to as TIM overflow. In some examples, TIM overflow 1611 can increase the contact area between TIM 16 and cover structure 14, thereby improving adhesion strength (or bonding force) between cover structure 14 and electronic component 12.

In some examples, TIM 16 can comprise multiple layers. For example, TIM 16 can comprise TIM layer 161, surface treatment layer 164, and metal TIM 165. In some examples, TIM layer 161 can comprise or be referred to as a non-metal TIM, such as graphite TIM. For example, TIM layer 161 can comprise graphite. TIM layer 161 can comprise exterior TIM side 162 and interior TIM side 163 opposite to exterior TIM side 162. Exterior TIM side 162 of TIM layer 161 can contact electronic component 12. Interior TIM side 163 is oriented toward and can contact metal TIM 165 or upper lid inner surface 145.

In some examples, surface treatment layer 164 is provided on interior TIM side 163. In some examples, surface treatment layer 164 can comprise or be referred to as a hydroxyl group (OH-group) layer or a hydroxylation layer. In some examples, surface treatment layer 164 can be formed by performing acid treatment on interior TIM side 163 of TIM layer 161 prior to coupling TIM layer 161 to metal TIM 165 or to upper lid inner surface 145. For example, surface treatment layer 164 can be formed by applying nitric acid (HNO₃) on a TIM layer 161 comprised of graphite. In some examples, surface treatment layer 164 can be formed by oxidizing interior TIM side 163 and then performing hydrogen plasma treatment. In some examples, surface treatment layer 164 can be formed by oxidizing interior TIM side 163 and then annealing under a hydrogen atmosphere. In some examples, oxidizing interior TIM side 163 can comprise annealing under an oxygen (02) atmosphere at a temperature of 400° C. or greater or performing an oxygen plasma treatment. In some examples, the hydroxyl groups of surface treatment layer 164 are associated with strong adsorption of a metal, such as gold. Surface treatment layer 164 can improve adhesion strength (or bonding force) between TIM layer 161 and metal TIM 165 or between TIM layer 161 and upper lid wall 141.

In some examples, metal TIM 165 can be provided between TIM layer 161 and upper lid wall 141. In some examples, metal TIM 165 can comprise gold (Au). In some examples, metal TIM 165 can be provided on upper lid inner surface 145 by sputtering, electroless plating, electrolytic plating, PVD, CVD, MOCVD, ALD, LPCVD, or PECVD. In some examples, metal TIM 165 can be provided on coating 147. In some examples, metal TIM 165 can be provided on upper lid wall 141, and TIM layer 161 having surface treatment layer 164 formed thereon can be coupled to metal TIM 165. In some examples, the thickness of metal TIM 165 can range from about 3 μm to about 10 μm. In some examples, TIM layer 161 having surface treatment layer 164 formed thercon can be in direct contact with upper lid wall 141 (e.g., metal TIM 165 may be omitted).

In some examples, cover structure 14 can be single-piece or integrated structure. In some examples, cover structure 14 can be a multiple-piece structure. In some examples, lid sidewalls 142 can comprise or be referred to as stiffeners. Lid sidewalls 142 can be formed on the edge (or perimeter) of upper lid wall 141 and can extend downward from upper lid wall 141. In some examples, lid sidewalls 142 can be continuously provided on the edge of upper lid outer surface 144. In some examples, lid sidewalls 142 can support upper lid wall 141. In some examples, lid sidewalls 142 can cover electronic components 12 and 13 in the lateral direction. Lid sidewalls 142 can comprise sidewall bottom 1421. In some examples, lid sidewalls 142 can be coupled to the top side of substrate 11 through lid bonding material 15. In some examples, lid bonding material 15 can be supplied (or dispensed) on sidewall bottom 1421 of lid sidewalls 142, and lid sidewalls 142 can be coupled to substrate 11 by curing lid bonding material 15 in response disposing lid sidewalls 142 on substrate 11. Sidewall bottom 1421 can be coupled to the top side of substrate 11 through lid bonding material 15. In some examples, lid sidewalls 142 are the only sidewalls include or integrate with cover structure 14. That is, in some examples lid cavity 143 is devoid of additional full or partial sidewalls, appendages, or partitions extending downward from upper wall inner surface 145.

In some examples, lid bonding material 15 can comprise or be referred to as an interface material, an adhesive, or a solder. In some examples, lid bonding material 15 can comprise a thermally curable adhesive, a photo-curable adhesive, or a non-curable adhesive (e.g., a rubber-based adhesive, an acryl-based adhesive, a vinyl alkyl ether-based adhesive, a silicone-based adhesive, a polyester-based adhesive, a polyamide-based adhesive, or a urethane-based adhesive). In some examples, lid bonding material 15 can be dielectric. In some examples, lid bonding material 15 can be electrically conductive. Lid bonding material 15 is provided between sidewall bottom 1421 and the top side of substrate 11. In some examples, the thickness of lid bonding material 15 can range from about 30 μm to about 300 μm.

FIG. 2E shows a cross-sectional view of electronic device 10 at a later stage of manufacture. In the example shown in FIG. 2E, external interconnects 17 can be provided on the bottom side of substrate 11. External interconnects 17 can be coupled to conductive structure 111 exposed to the bottom side of substrate 11. For example, external interconnects 17 can be coupled to outer contact pads 1110 of conductive structure 111. In some examples, external interconnects 17 can comprise or be referred to as solder balls, solder coated metal (e.g., copper) core balls, pillars, pillars with solder caps, or bumps with solder caps. External interconnects 17 can comprise tin (Sn), silver (Ag), lead (Pb), copper (Cu), Sn—Pb, Sn37-Pb, Sn95-Pb, Sn—Pb—Ag. Sn—Cu, Sn—Ag, Sn—Au, Sn—Bi, or Sn—Ag—Cu. In some examples, external interconnects 17 can be provided through a reflow process after forming a conductive material including solder on the bottom side of substrate 11 in a ball drop method. External interconnects 17 can couple electronic device 10 to an external device. In some examples, the thickness of each of external interconnects 17 can range from about 50 μm to about 1000 μm.

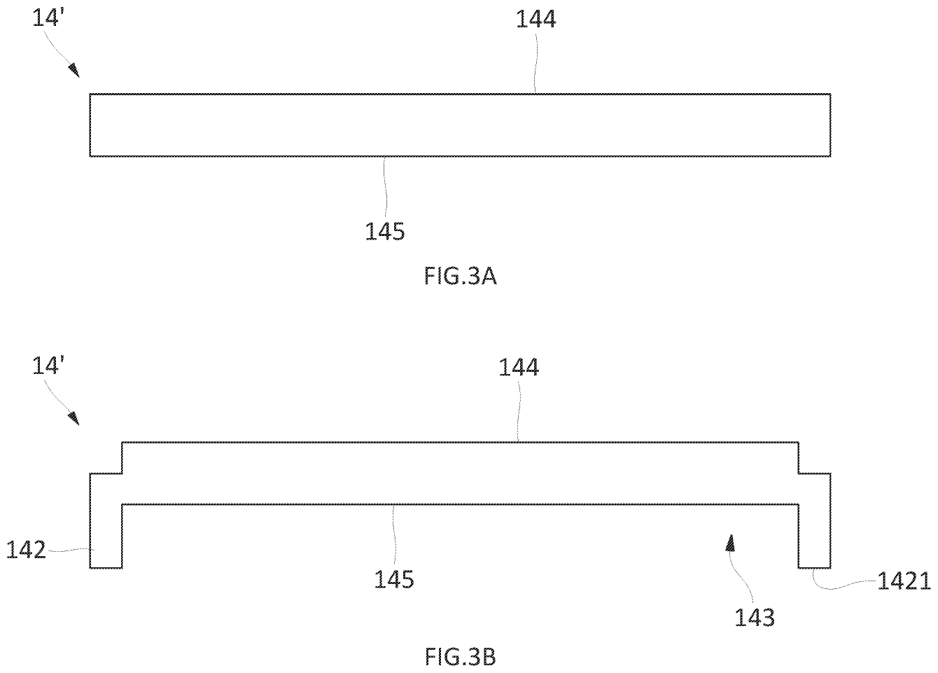

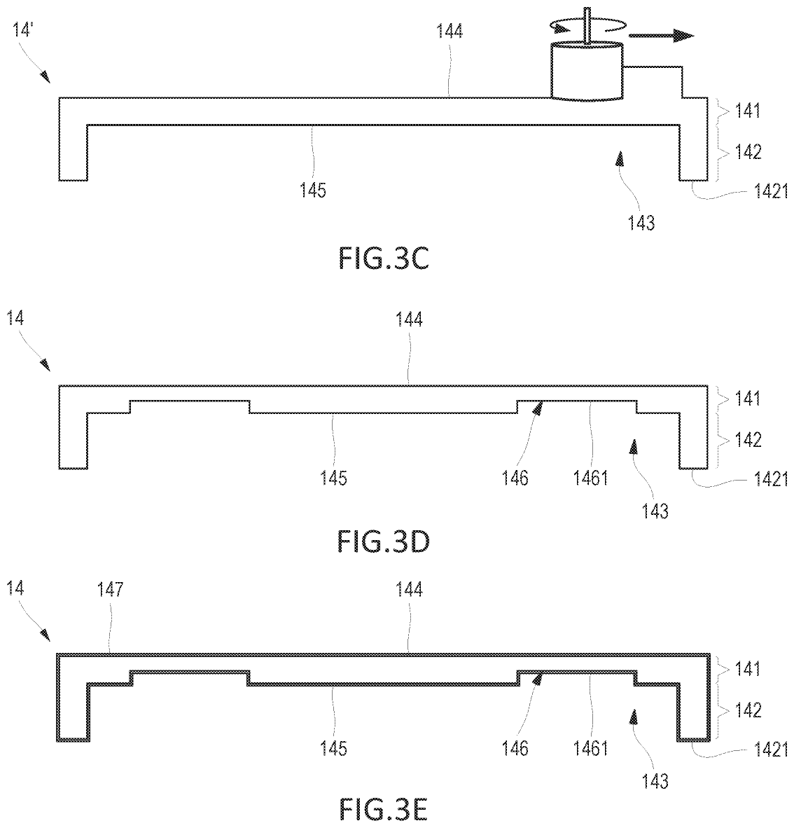

FIGS. 3A to 3E show cross-sectional views of an example method for manufacturing an example cover structure, such as cover structure 14 in FIG. 1.

FIG. 3A is a cross-sectional view of cover structure 14 at an early stage of manufacture. In the example shown in FIG. 3A, raw material 14′ is provided. Raw material 14′ can comprise a metal material, such as, for example, copper, a copper alloy, nickel, a nickel alloy, or stainless steel. Raw material 14′ can also be referred to as a work piece.

FIG. 3B shows a cross-sectional view of cover structure 14 at a later stage of manufacture. In the example shown in FIG. 3B, lid sidewalls 142 and lid cavity 143 can be formed in raw material 14′ through a stamping process. For example, punching die may be employed to cause the edge region of raw material 14′ to protrude downward, thereby forming lid sidewalls 142 extending downward from upper lid inner surface 145 and lid cavity 143 located inside lid sidewalls 142.

FIG. 3C shows a cross-sectional view of cover structure 14 at a later stage of manufacture. In the example shown in FIG. 3C, upper lid wall 141 can be formed by planarizing upper lid outer surface 144 using a milling or grinding process. For example, the stamping process (shown in FIG. 3B) can generate a portion of raw material 14′ protruding outwardly from upper lid outer surface 144. This outwardly protruding portion can be removed be removed by a milling or grinding process, thereby leaving generally planar upper lid outer surface 144.

FIG. 3D shows a cross-sectional view of cover structure 14 at a later stage of manufacture. In the example shown in FIG. 3D, one or more TIM channels 146 can be provided in upper lid wall 141. For example, TIM channels 146 can be formed in upper lid inner surface 145 using a milling or etching process. In some examples, TIM channels 146 can be formed by removing a portion of upper lid inner surface 145 by masking and chemical etching. Upper lid wall 141, lid sidewalls 142, lid cavity 143, and TIM channels 146 can be referred to as cover structure 14. In some examples, lid sidewalls 142 of cover structure 14 comprise a continuous structure that completely encloses lid cavity 143.

FIG. 3E shows a cross-sectional view of cover structure 14 at a later stage of manufacture. In the example shown in FIG. 3E, coating 147 can be provided on the surfaces of cover structure 14. For example, coating 147 can be provided on surfaces of upper lid wall 141 and lid sidewalls 142. In some examples, coating 147 can comprise or be referred to as a conductive coating or a plating. In some examples, coating 147 can comprise an electrically conductive material, such as nickel, gold, silver, platinum, or tin. In some examples, coating 147 can be provided by electroless plating, electrolytic plating, or sputtering. In some examples, the thickness of coating 147 can range from about 3 μm to about 15 μm.

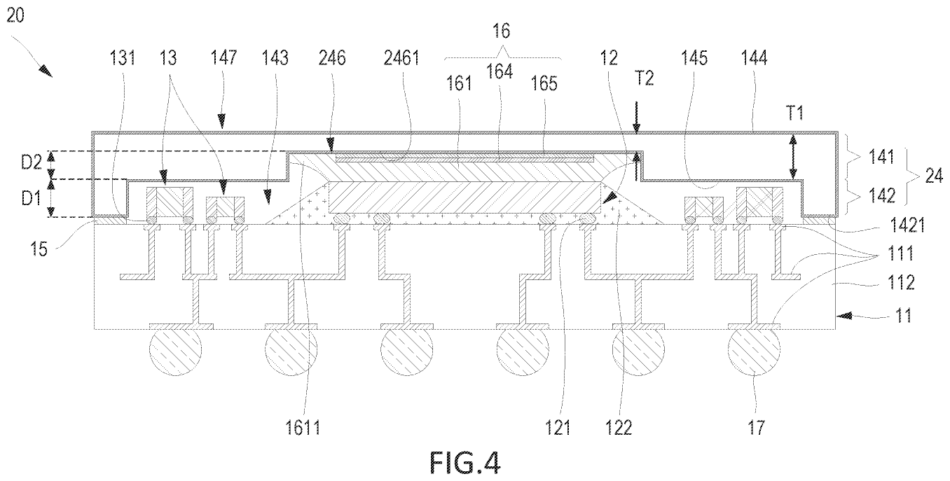

FIG. 4 shows a cross-sectional view of an example electronic device 20. In the example shown in FIG. 4, electronic device 20 can comprise substrate 11, electronic components 12 and 13, cover structure 24, lid bonding material 15, TIM 16, and external interconnects 17. In some examples, electronic device 20 can comprise similar elements, features, materials, or formation processes to those of electronic device 10, as previously described. Cover structure 24 can comprise upper lid wall 141, lid sidewalls 142, lid cavity 143, upper lid outer surface 144, upper lid inner surface 145, TIM channel 246, and coating 147.

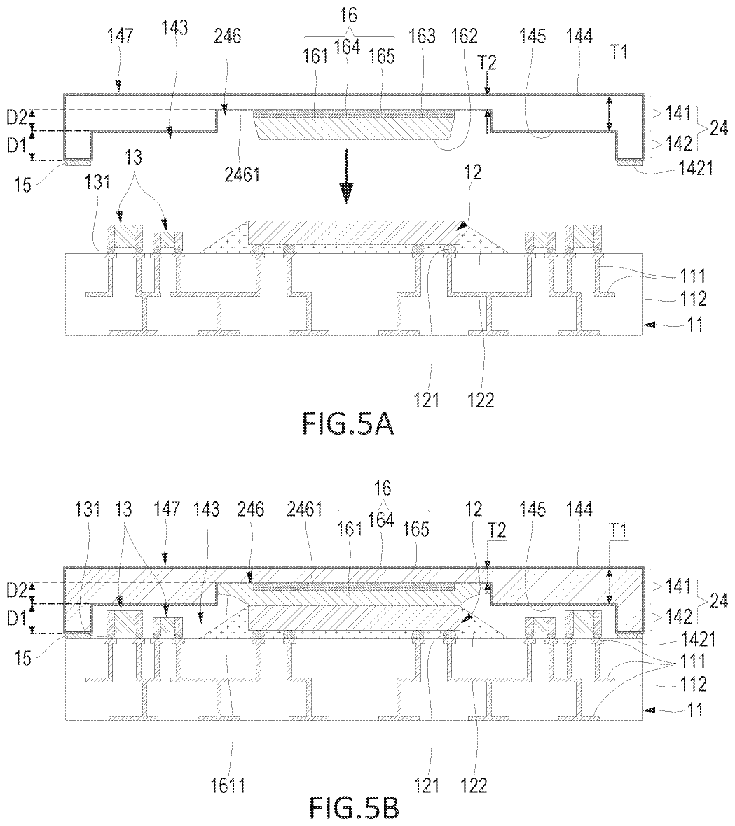

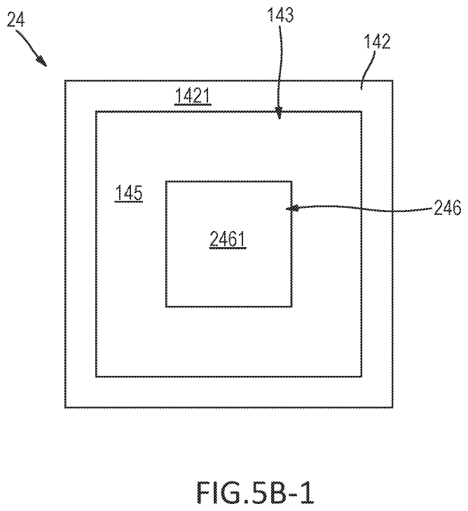

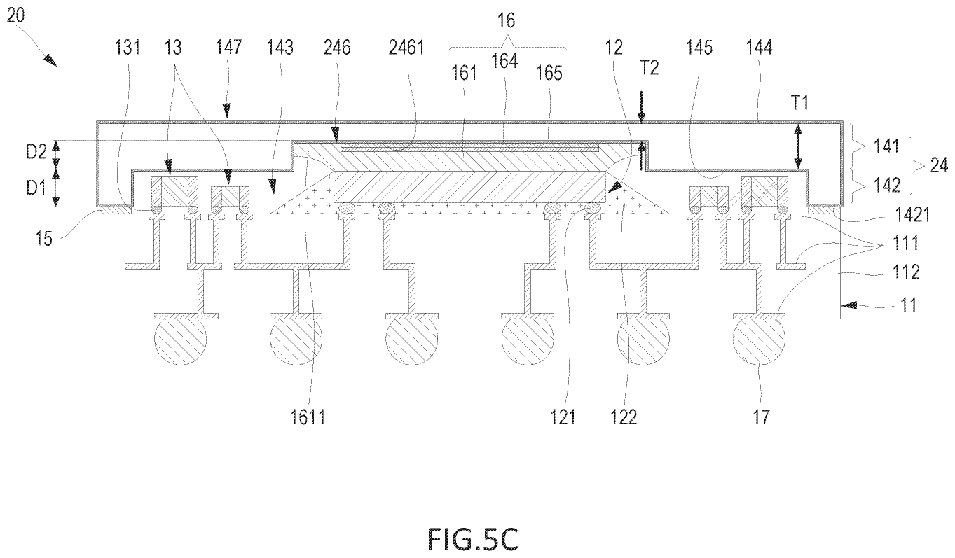

FIGS. 5A to 5C show cross-sectional views of an example method for manufacturing an example electronic device, such as electronic device 20 in FIG. 4.

FIGS. 5A and 5B are cross-sectional views of electronic device 20 at an early stage of manufacture. FIG. 5B-1 shows a bottom-up view of cover structure 24. In the example shown in FIG. 5A, the steps described with respect to FIGS. 2A and 2B can be followed, and then cover structure 24 can be provided on substrate 11. Cover structure 24 can be provided over electronic components 12 and 13. In some examples, cover structure 24 can comprise similar elements, features, materials, or formation processes to those of cover structure 14, as previously described.

In some examples, TIM channel 246 can be provided in upper lid inner surface 145 of upper lid wall 141. TIM channel 246 can be provided in a central portion of upper lid inner surface 145, where electronic component 12 is attached. For example, the central portion of upper lid inner surface 145 can be vertically aligned with electronic component 12. In some examples, the area (or footprint) of TIM channel 246 can be greater than the area (or footprint) of electronic component 12. In the example shown in FIG. 5B-1, TIM channel 246 can be a single groove, trench, or channel provided in upper lid wall 141. TIM channel 246 can comprise TIM channel floor 2461. TIM channel floor 2461 is recessed with respect to upper lid inner surface 145. TIM channel 246 is an example of a channel structure.

Lid cavity 143 can be defined by upper lid wall 141 and lid sidewalls 142. Electronic components 12 and 13 can be accommodated in lid cavity 143. In some examples, the thickness T1 of upper lid wall 141, as measured between upper lid outer surface 144 and upper lid inner surface 145, can range from about 200 μm to 4000 μm. In some examples, the thickness T2 of upper lid wall 141, as measured between upper lid outer surface 144 and TIM channel floor 2461, can range from about 100 μm to about 3900 μm. In some examples, the depth D1 of lid cavity 143, as measured between upper lid inner surface 145 and sidewall bottom 1421, can range from about 50 μm to about 1600 μm. The depth D1 of lid cavity 143 can correspond to the thickness of lid sidewalls 142. In some examples, the depth D2 of TIM channel 246, measured between upper lid inner surface 145 and TIM channel floor 1461, can range from about 100 μm to about 300 μm. In some examples, lid sidewalls 142 are the only sidewalls of cover structure 24. That is, in some examples lid cavity 143 is devoid of additional full or partial sidewalls, appendages, or partitions extending downward from upper wall inner surface 145. In some examples, cover structure can include a combination of TIM channels 146 and TIM channel 246.

In accordance with various examples and as shown in FIG. 5A, TIM 16 can be provided at the center of TIM channel floor 2461. As shown in FIG. 5B, when upper lid wall 141 is pressed toward electronic component 12, TIM 16 can flow away from the center of TIM channel floor 2461 and toward the sidewalls of TIM channel 246. In some examples, prior to coupling to electronic component 12, TIM 16 can have an area (or footprint) that is equal to or that is less than the area (or footprint) of electronic component 12. As shown in FIG. 5B, after coupling TIM 16 to electronic component 12, TIM overflow 1611 can be outside the footprint of electronic component 12.

FIG. 5C shows a cross-sectional view of electronic device 20 at a later stage of manufacture. In the example shown in FIG. 5C, external interconnects 17 can be provided on the bottom side of substrate 11, as previously described with reference to FIG. 2E.

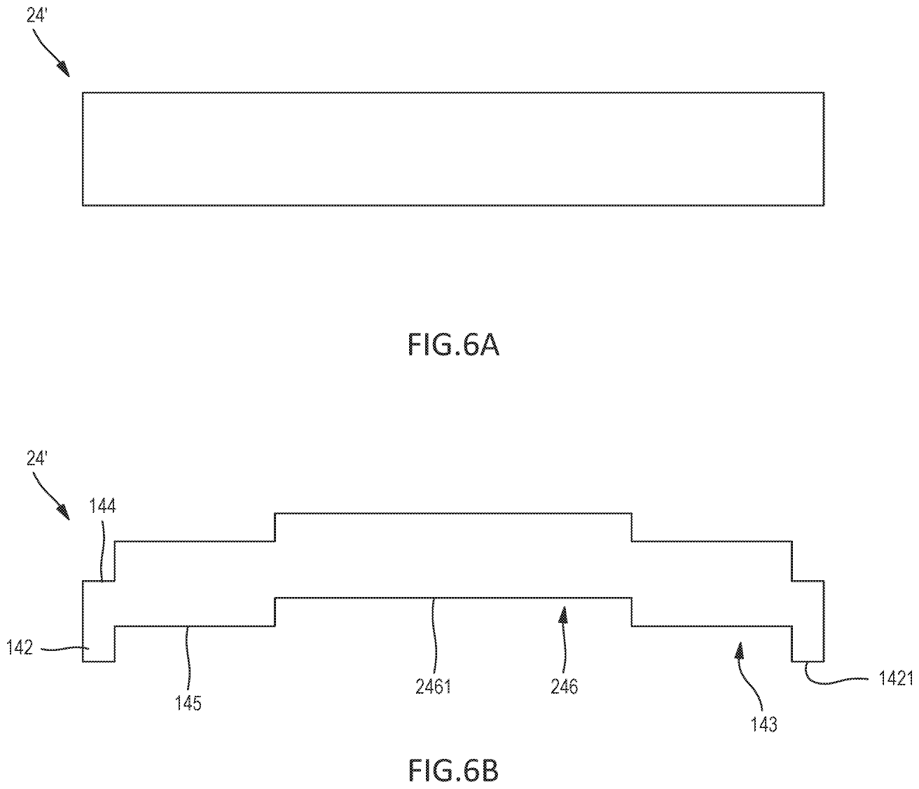

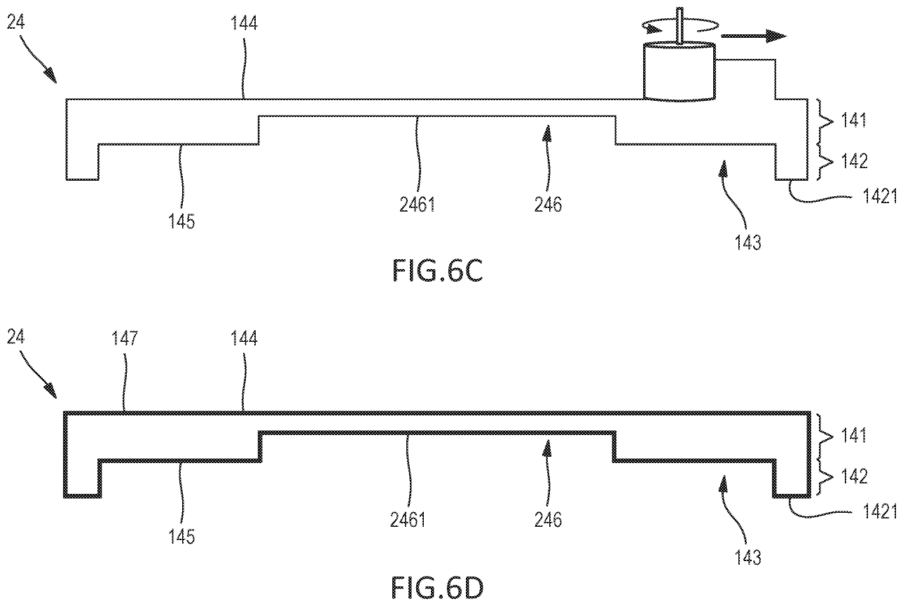

FIGS. 6A to 6D show cross-sectional views of an example method for manufacturing an example cover structure, such as cover structure 24 in FIG. 4.

FIG. 6A is a cross-sectional view of cover structure 24 at an early stage of manufacture. In the example shown in FIG. 6A, raw material 24′ can be provided. In some examples, raw material 24′ can comprise similar elements, features, materials, or formation processes to those of raw material 14′, as previously described. Raw Material 24′ can also be referred to as a work piece.

FIG. 6B shows a cross-sectional view of cover structure 24 at a later stage of manufacture. In the example shown in FIG. 6B, lid sidewalls 142, lid cavity 143, and TIM channel 246 can be provided in raw material 24′ using, for example, a stamping process. In some examples, by forming the edge of raw material 24′ so as to protrude downward using, for example, a punching die, lid sidewalls 142 and lid cavity 143 located inside lid sidewalls 142 can be provided. In some examples, the punching die can also cause the central portion of lid cavity 143 to protrude upward, thereby providing TIM channel 246 in upper lid inner surface 145. TIM channel floor 2461, which is recessed with respect to upper lid inner surface 145, can be provided by the punching die.

FIG. 6C shows a cross-sectional view of cover structure 24 at a later stage of manufacture. In the example shown in FIG. 6C, upper lid wall 141 can be formed by planarizing upper lid outer surface 144 through a milling or grinding process. For example, the stamping process can form a portion of raw material 24′ protruding from upper lid outer surface 144. This protruding portion can be removed by a milling or grinding process, thereby providing generally planar upper lid outer surface 144. Upper lid wall 141, lid sidewalls 142, lid cavity 143, and TIM channel 246 can be referred to as cover structure 24. In some examples, lid sidewalls 142 of cover structure 24 comprise a continuous structure that completely encloses lid cavity 143.

FIG. 6D shows a cross-sectional view of cover structure 24 at a later stage of manufacture. In the example shown in FIG. 6D, coating 147 can be provided on the surfaces of cover structure 24.

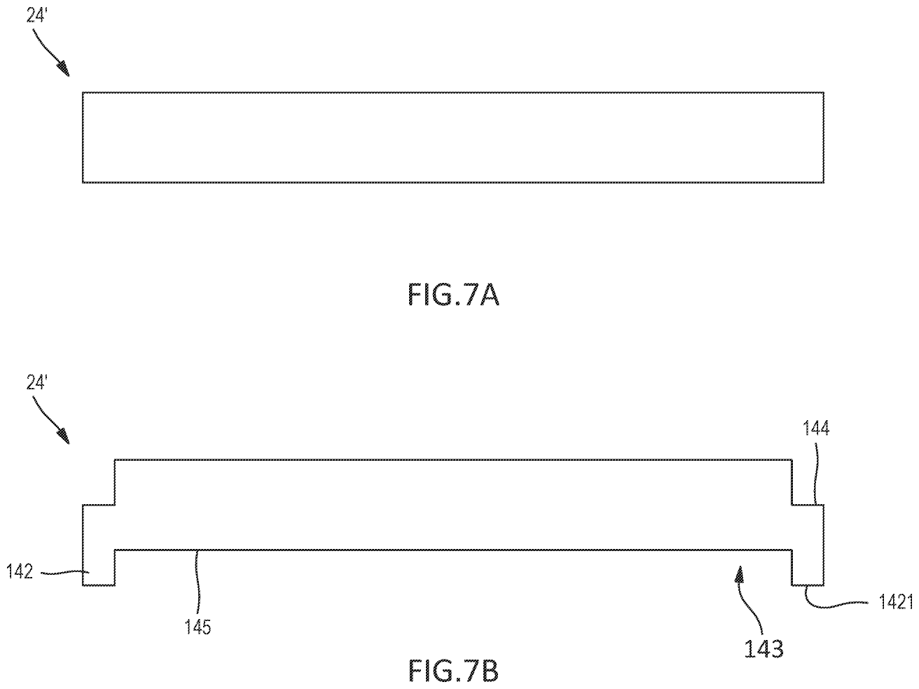

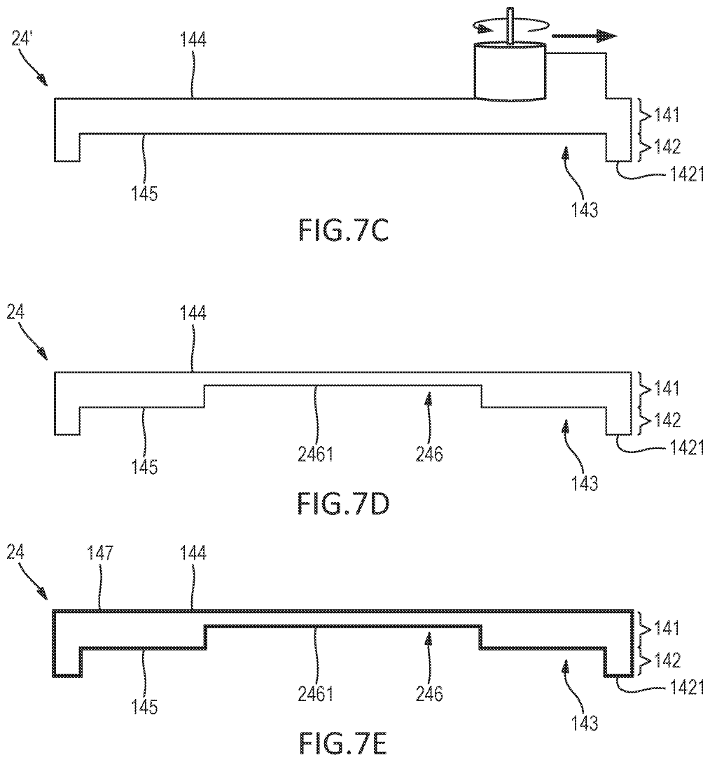

FIGS. 7A to 7E show cross-sectional views of an example method for manufacturing an example cover structure, such as cover structure 24 in FIG. 4.

FIG. 7A is a cross-sectional view of cover structure 24 at an early stage of manufacture. In the example shown in FIG. 7A, raw material 24′ is provided. In some examples, raw material 24′ can comprise similar elements, features, materials, or formation processes to those of raw material 14′, as previously described.

FIG. 7B shows a cross-sectional view of cover structure 24 at a later stage of manufacture. In the example shown in FIG. 7B, lid sidewalls 142 and lid cavity 143 can be formed in raw material 24′ using, for example, a stamping process. In some examples, by forming the edge of raw material 24′ so as to protrude downward by using a punching die, lid sidewalls 142 and lid cavity 143 located inside lid sidewalls 142 can be provided.

FIG. 7C shows a cross-sectional view of cover structure 24 at a later stage of manufacture. In the example shown in FIG. 7C, upper lid wall 141 can be formed by planarizing upper lid outer surface 144 using, for example, a milling or grinding process.

FIG. 7D shows a cross-sectional view of cover structure 24 at a later stage of manufacture. In the example shown in FIG. 7D. TIM channel 246 can be formed in lid cavity 143 using, for example, a milling or a masking and etching process. TIM channel 246 can be provided at the center of upper lid inner surface 145. In some examples, TIM channel 246 can be formed by removing a portion of upper lid inner surface 145 by chemical etching.

FIG. 7E shows a cross-sectional view of cover structure 24 at a later stage of manufacture. In the example shown in FIG. 7E, coating 147 can be provided on the surface of cover structure 24.

In summary, electronic devices and methods of manufacturing electronic devices have been described, which include a lid structure with one or more channels proximate to a TIM structure that accommodate(s) the flow of TIM material when the lid structure is coupled to a substrate or an electronic component. Among other things, the channel prevents the TIM material from encroaching on other electronic components, which can cause reliability issues. In some examples, the lid structure can be provided using stamping techniques, masking and etching techniques, or combinations thereof. In some examples, the TIM structure can comprise an insulating TIM layer and a conductive layer. In some examples, the insulating TIM layer can be subjected to a surface treatment process to enhance the adhesion strength of the TIM structure to the lid structure.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate;
a cover structure comprising:
an upper cover wall comprising an upper wall outer surface and an upper wall inner surface opposite to the upper wall outer surface;
cover sidewalls extending from the upper wall inner surface and coupled to the substrate, the upper cover wall and the cover sidewalls defining a cavity; and
a channel structure in the upper cover wall extending inward from the upper wall inner surface;
a first electronic component coupled to the substrate within the cavity; and
a thermal interface material (TIM) coupled to the upper wall inner surface and the first electronic component;
wherein:
a portion of the TIM is within the channel structure.

2. The electronic device of claim 1, wherein:
the channel structure comprises a plurality of individual channels.

3. The electronic device of claim 2, wherein:
the upper wall inner surface comprises a portion that overlies the first electronic component; and
the plurality of individual channels is disposed on at least one side of the portion that overlies the first electronic component.

4. The electronic device of claim 3, wherein:
the portion that overlies the first electronic component comprises a first footprint;
the first electronic component comprises a second footprint; and
the first footprint is greater than the second footprint.

5. The electronic device of claim 2, wherein:
the plurality of individual channels are separated by a pitch in a range from about 200 microns to about 2000 microns.

6. The electronic device of claim 1, further comprising:
an underfill;
wherein:
the substrate comprises a top side;
the first electronic component comprises a first side, a second side opposite to the first side, and a lateral side connecting the first side to the second side;
the second side is coupled to the top side of the substrate; and
the underfill contacts the top side of the substrate and the second side of the first electronic component and covers at least a portion of the lateral side of the first electronic component.

7. The electronic device of claim 1, wherein:
the channel structure comprises a single groove;
the single groove comprises a channel floor recessed with respect to the upper wall inner surface;
the channel floor overlies the first electronic component; and
the TIM extends between the channel floor and the first electronic component.

8. The electronic device of claim 1, wherein:
the TIM comprises:
a TIM layer adjacent to the first electronic component; and
a metal TIM layer interposed between the TIM layer and the upper wall inner surface.

9. The electronic device of claim 8, wherein:
the TIM layer comprises graphite.

10. The electronic device of claim 1, further comprising:
second electronic components coupled to the substrate within the cavity;
wherein:
the channel structure overlaps at least one of the second electronic components.

11. The electronic device of claim 1, further comprising:
a coating over the upper cover wall and the cover sidewalls.

12. An electronic device, comprising:
a substrate comprising a conductive structure and a dielectric structure;
a lid structure comprising:
an upper lid wall comprising an upper wall outer surface and an upper wall inner surface opposite to the upper wall outer surface;
a lid sidewall extending from the upper lid wall and coupled to the substrate; and
a channel structure extending inward from the upper wall inner surface towards the upper wall outer surface;
wherein:
the upper lid wall and the lid sidewall define a lid cavity;
a first electronic component comprising a first side, a second side opposite to the first side, and a lateral side connecting the first side to the second side;
wherein:
the lateral side defines a first footprint; and
the first side is coupled to the conductive structure within the lid cavity; and
a thermal interface material (TIM) interposed between the second side of the first electronic component and the upper lid wall;
wherein:
at least portion of the channel structure is laterally outside of the first footprint; and
at least a portion of the TIM is inside the channel structure.

13. The electronic device of claim 12, wherein:
the channel structure comprises a single groove;
the single groove comprises:
a recessed floor extended inward from the upper wall inner surface; and
groove sidewalls extending between the recessed floor and the upper wall inner surface;
the recessed floor comprises a second footprint greater than the first footprint; and
the TIM is inside the single groove and is coupled to the recessed floor.

14. The electronic device of claim 12, wherein:
the upper wall inner surface comprises a portion that overlies the first electronic component;
the channel structure comprises a plurality of channels disposed proximate to the portion that overlies the first electronic component; and
the plurality of channels extend laterally beyond the first footprint.

15. The electronic device of claim 14, wherein:
the portion that overlies the first electronic component comprises a plurality of sides;
the plurality of channels is distributed around each of the plurality of sides; and
the TIM comprises:
a TIM layer comprising a non-metal adjacent to the first electronic component; and
a metal TIM layer interposed between the TIM layer and the upper wall inner surface.

16. A method of manufacturing an electronic device, comprising:
providing a substrate comprising a conductive structure and a dielectric structure;
providing a first electronic component comprising a first side and a second side opposite to the first side;
providing a lid structure comprising:
an upper lid wall comprising an upper wall outer surface and an upper wall inner surface opposite to the upper wall outer surface;
lid sidewalls extending from the upper lid wall; and
a channel structure extending inward from the upper wall inner surface towards the upper wall outer surface;
providing a thermal interface material (TIM);
coupling the first side of the first electronic component to the conductive structure; and
coupling the upper lid wall to the second side of the first electronic component with the TIM and coupling the lid sidewalls to the substrate;
wherein:
the channel structure accommodates flow of the TIM in response to the coupling of the upper lid wall to the second side of the first electronic component.

17. The method of claim 16, wherein providing the lid structure comprises:
providing the channel structure comprising a plurality of individual channels disposed adjacent to a portion of the upper lid wall that overlies the first electronic component.

18. The method of claim 16, wherein providing the lid structure comprises:
providing the channel structure comprising a single groove including a channel floor recessed with respect to the upper wall inner surface;
wherein:
the channel floor overlies the first electronic component; and
the TIM extends between the channel floor and the first electronic component.

19. The method of claim 16, wherein providing the lid structure comprises:
providing a work piece having a top side and a lower side opposite the top side;
forming a recessed region extending inward from the lower side of the work piece, the recessed region comprising the lid sidewalls and the upper wall inner surface; and
in either order:
(a) removing a portion of the top side of the work piece to provide the upper wall outer surface; and
(b) forming the channel structure in the upper wall inner surface.

20. The method of claim 19, wherein:
forming the recessed region comprising stamping the lower side of the work piece;
forming the channel structure comprises stamping the channel structure into the recessed region; and
removing the portion of the top side comprises removing the portion of the top side after forming the channel structure.
